(19) United States
(12) Patent Application Publication
(10) Pub. No.: US 2009/0309155 A1
(43) Pub. Date: Dec. 17, 2009

(54) VERTICAL TRANSISTOR WITH INTEGRATED ISOLATION

(76) Inventor: Aram H. Mkhitarian, Glendale, CA (US)

Correspondence Address: CHRISTOPHER P. MAIORANA, P.C., 24840 HARPER SUITE 100, ST. CLAIR SHORES, MI, 48080, US

(21) Appl. No.: 12/138,273

(22) Filed: Jun. 12, 2008

(51) Int. Cl. H01L 49/00; H01L 21/76

(52) U.S. Cl. 257/327; 438/439; 257/E49.001; 257/E21.54

(57) ABSTRACT

A vertical transistor with integrated isolation is provided. The vertical transistor includes a vertical semiconductor structure and an isolation layer on a bottom surface of the vertical semiconductor structure. The vertical transistor further includes a plurality of terminals on a top surface of the vertical semiconductor structure.

### BACKGROUND OF THE INVENTION

This invention relates generally to transistors having a vertical structure, and more particularly, to transistors with vertical structures that include integrated isolation.

Transistors having vertical structures (e.g., radio frequency (RF) power transistors) use the back side of the transistor chip as the drain/collector terminal for the chip. For example, power Metal-Oxide-Semiconductor Field-Effect Transistors (MOSFETs) may be formed using a double-diffused metal oxide semiconductor (DMOS) technology that results in a structure defining a vertical device having two terminals on the top of the chip and one terminal on the bottom of the chip. Electrical current flows vertically downward in these chips. However, because most of these chips are in a common emitter/source or common base configuration, the terminal on the bottom of the chip is not the common terminal that needs to be grounded. Accordingly, these chips cannot be placed directly on a conductor or mounting surface of a chip package. Thus, these chips require packaging that includes an insulating layer, for example, a beryllium oxide (BeO) or an aluminum nitride (AlN) layer in order to isolate the terminal on the bottom of the chip (e.g., the drain/collector) from the ground terminal when mounted to the packaging. The chip must be mounted to the insulating layer (e.g., dielectric layer) and then the ground is connected to the packaging. For example, in a bi-polar transistor chip, the top terminals are the emitter and base, which are wired to ground, such as by wire bonding. In a MOSFET chip, the top terminal is the source, which is wired to ground.

As a result of having to include the insulating layer as part of the chip packages, the chip packages require additional processing steps and an additional layer. This additional processing adds time and cost as compared to chip packages that do not include the insulating layer. Also, because of the relatively poor thermal conductivity of BeO and AlN materials, packages with an insulating layer have a much higher thermal impedance than non-insulating packages.

### BRIEF DESCRIPTION OF THE INVENTION

In accordance with an exemplary embodiment, a vertical transistor structure is provided that includes a vertical semiconductor structure and an isolation layer on a bottom surface of the vertical semiconductor structure. The vertical transistor structure further includes a plurality of terminals on a top surface of the vertical semiconductor structure.

In accordance with another exemplary embodiment, a power transistor is provided that includes a semiconductor chip having a top surface and a bottom surface. The power transistor further includes a plurality of terminals on the top surface of the semiconductor chip and an integrated isolation region on the bottom surface of the semiconductor chip.

In accordance with yet another exemplary embodiment, a method of fabricating a vertical transistor structure is provided. The method includes forming a plurality of terminals on a top surface of a semiconductor chip. The method further includes forming an integrated isolation layer on a bottom surface of the semiconductor chip such that electrical current flowing vertically downward from at least one of the plurality of terminals is blocked and directed vertically upward to another one of the plurality of terminals.

### BRIEF DESCRIPTION OF THE DRAWINGS

FIG. 1 is a diagram of a Metal Oxide Semiconductor Field-Effect Transistor (MOSFET) constructed in accordance with various embodiments of the invention.

FIG. 2 is a diagram of a Bipolar Junction Transistor (BJT) constructed in accordance with various embodiments of the invention.

FIG. 3 is a cross-sectional view of a MOSFET constructed in accordance with various embodiments of the invention.

FIG. 4 is a diagram of a MOSFET constructed in accordance with various embodiments of the invention showing electrical current flow within the MOSFET.

FIG. 5 is a top perspective view of a MOSFET constructed in accordance with various embodiments of the invention mounted to a non-insulating package.

FIG. 6 is a side elevation view of a portion of the non-insulating package of FIG. 5 showing the MOSFET mounted thereto.

FIG. 7 is a top view of a chip having a package configuration formed in accordance with various embodiments of the invention.

### DETAILED DESCRIPTION OF THE INVENTION

For simplicity and ease of explanation, the invention will be described herein in connection with various embodiments thereof. Those skilled in the art will recognize, however, that the features and advantages of the various embodiments may be implemented in a variety of configurations. It is to be understood, therefore, that the embodiments described herein are presented by way of illustration, not of limitation.

As used herein, an element or step recited in the singular and proceeded with the word “a” or “an” should be understood as not excluding plural said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property. Additionally, the arrangement and configuration of the various components described herein may be modified or changed, for example, replacing certain components with other components or changing the order or relative positions of the components.

Various embodiments of the invention provide a transistor architecture, for example, a vertical transistor architecture such as a radio frequency (RF) or power transistor architecture having the transistor terminals on a top surface of a semiconductor chip forming the transistor. The transistor architecture also includes integrated die-to-ground isolation. In particular, an isolation layer is formed during the semiconductor chip fabrication process such that the insulation layer forms part of the semiconductor chip transistor device. As a result of having integrated isolation, an insulated chip package, for example, packaging that includes an insulating layer, such as, a beryllium oxide (BeO) or an aluminum nitride (AlN) layer is not needed to isolate the terminal on the bottom of the chip. For example, the drain/collector typically on the bottom of the transistor chip does not have to be isolated from the ground terminal using an isolation layer within the chip package when mounted to the chip package.

The various embodiments provide a transistor architecture forming a semiconductor device that includes a vertical structure wherein electrical current flows from the an input terminal a the top of the device downward through the semiconductor material. The electrical current flow is blocked on the bottom of the vertical structure by an isolation layer. It should be noted that the various embodiments are not limited to particular transistors or power devices and may be configured, for example, as any type of power of vertical structure transistor. For example, the various embodiments may provide a Metal Oxide Semiconductor Field-Effect Transistor (MOSFET), a Bipolar Junction Transistor (BJT), a heterojunction bipolar transistor (HBT), etc. Different fabrication processes also may used to form the different transistor devices. For example, a Double-Diffused Metal Oxide Semiconductor (DMOS) process may be used to form a MOSFET in accordance with various embodiments of the invention.

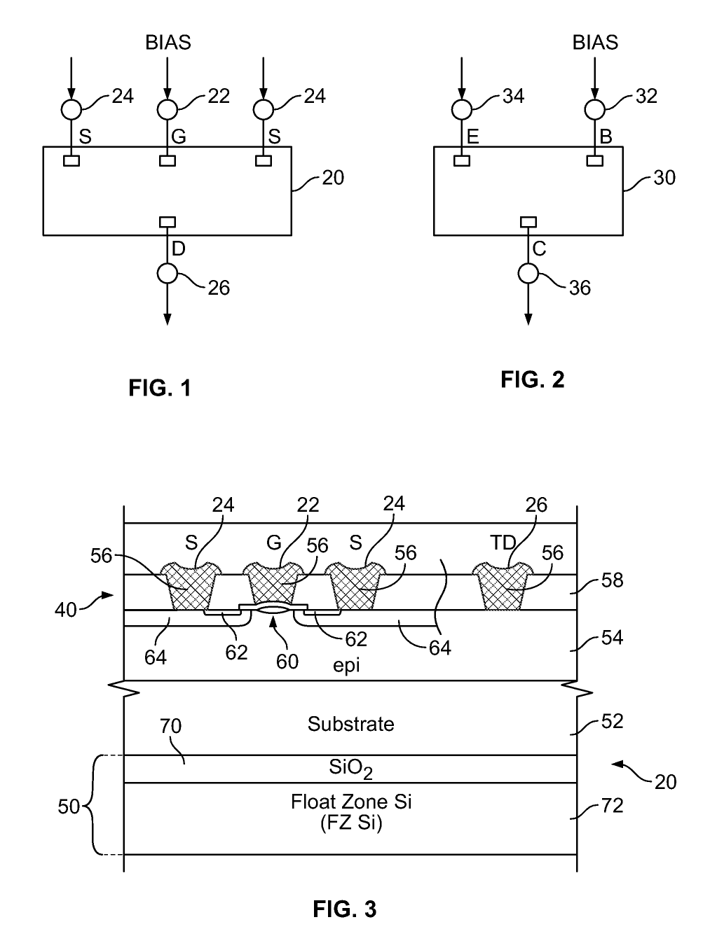

In accordance with various embodiments of the invention, a transistor having a vertical structure may be provided. For example, a power MOSFET 20 as shown in FIG. 1 may be provided that is configured to mount directly to a non-insulating package as described in more detail below. The power MOSFET 20 may be mounted directly within the package, such as to a copper pad. The power MOSFET 20 has a vertical structure and the voltage rating of the power MOSFET 20 is a function of doping and thickness (in particular of the N epitaxial layer) and the current rating is a function of a semiconductor channel width within the power MOSFET 20. Accordingly, the power MOSFET 20 can sustain high blocking voltage (e.g., 30 volts) at a high current (e.g., 120 amperes) using a compact piece of silicon.

In operation, and as is known, when a bias voltage is applied to a gate 22 of the power MOSFET 20, electrical current flow is provided from one or more sources 24 of the power MOSFET 20 to one or more drains 26 (a single drain 26 is illustrated in FIG. 1) of the power MOSFET 20. The power MOSFET 20 may operate at different voltage levels, for example, at voltages up to about 200 volts. The power MOSFET 20 may be used, for example, in any type of switching operation application wherein the power MOSFET 20 is switched between an on and off state. For example, the power MOSFET 20 or any transistor constructed in accordance with various embodiments of the invention may be used in RF communication systems having high frequency operation.

The various embodiments may provide different types of transistor devices and are not limited to the power MOSFET 20. For example, a BJT 30 as shown in FIG. 2 may be provided that includes, as is known, a base 32, an emitter 34 and a collector 36. Depending on the type of BJT 30 (e.g., PNP type or NPN type), when a bias voltage is applied to the base 32, electrical current flow is provided between the emitter 34 and collector 36 in a direction based on whether the BJT 30 is of a PNP or NPN type.

In the various embodiments, the terminals of the transistor, for example, the gate 22, source 24 and drain 26 of the power MOSFET 20 and the base 32, emitter 34 and collector 36 of the BJT 30 are formed on a top surface of the semiconductor chip, such as shown in FIGS. 1 and 2. Any suitable semiconductor fabrication process may be used to form the transistor device with metallizations on the top surface defining the terminals. For example, the terminals of the transistor may all be formed on a top surface using a reduced surface field double diffused metal oxide semiconductor (RESURF DMOS) transistor as described in U.S. Pat. No. 5,640,034. In general, as shown in FIG. 3, the gate 22, source 24 and drain 26 of the power MOSFET 20 are formed on a top surface 40 of the vertical structure. It should be noted that the various layers of the vertical structure of the power MOSFET 20 (or any transistor device formed in accordance with various embodiments of the invention) may be formed using any known semiconductor fabrication process.

In various embodiments, the vertical structure forming the power MOSFET 20 is a multilayer structure having an isolation region 50 that is electrically isolating and thermally conducting. The isolation region 50 may be formed from one or more layers as described below. The isolation region 50 is formed during the semiconductor fabrication process that forms the power MOSFET 20. Specifically, a substrate 52, for example, a silicon wafer is formed with the isolation region 50 formed on a bottom surface of the silicon wafer. The substrate 52 may be a heavily doped P type substrate. An epitaxial layer 54, for example, an N type epitaxial layer 54 is grown on the substrate 52 as is known. For example, the substrate 52 may be formed from an N+ silicon material and the epitaxial layer 54 formed from an N− silicon material. The substrate 52 and epitaxial layer 54 may be doped by adding impurities of desired concentrations.

The terminals (e.g., gate 22, source 24 and drain 26) of the power MOSFET 20 are formed on top of the epitaxial layer 54 by metallizations 56a-56c, which may be provided using a metal deposition process as is known. A channel 60 is formed under the gate metallization 56b by a gate oxide that contacts N type junctions 62, which are also in contact with the source metallizations 56a. P type implant regions 64 are also formed (e.g., implanted) below the source metallizations 56a and the N type junctions 62. It should be noted that the various layers, implantations and metallizations may be formed using any suitable doping, photolithography and etching process as are known in the art.

With particular reference now to the isolation region 50 below the substrate 52, the isolation region 50 is formed from one or more isolation layers, for example, a dielectric layer 70, which may be any non-conducting substance (as opposed to a conducting ground layer or ground plane as typically provided). In various embodiments, the dielectric layer 70 is formed from a material that is electrically isolating to block electrical current flow and thermally conducting to conduct heat from the power MOSFET 20. The dielectric layer 70 may be formed, for example, from silicon dioxide (SiO₂), also known as silica. The isolation region 50 also may include a float zone layer 72, for example, formed from Silicon (Si) and acting as the base of the power MOSFET 20. Thus, a silicon chip forming the power MOSFET 20 includes electrical isolation on a back or lower surface of the chip. The float zone layer 72 and dielectric layer 70 essentially form an electrically isolating or insulating base on which the vertical structure of the power MOSFET 20 is formed.

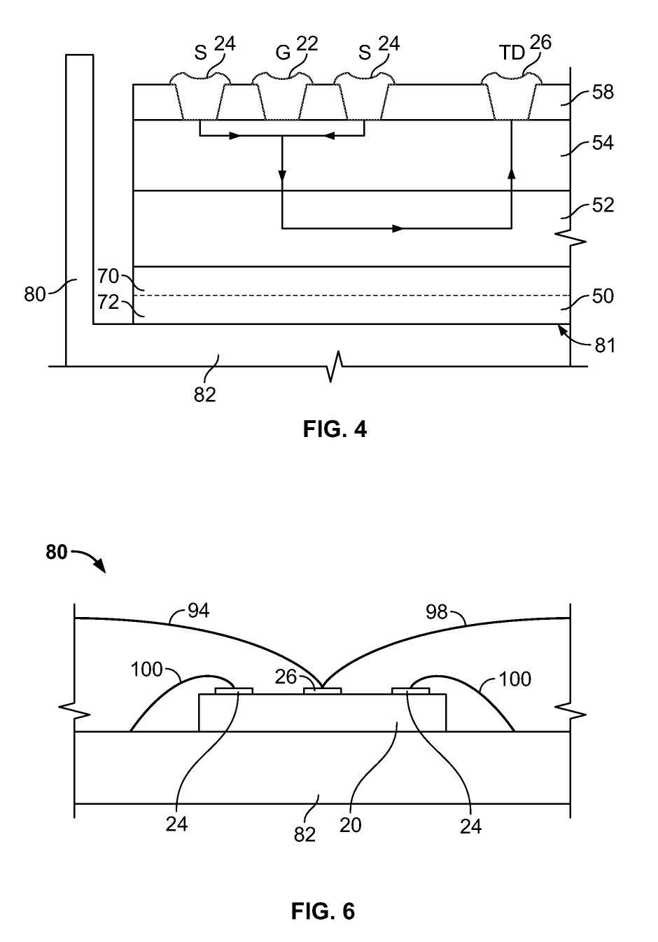

In operation, and with reference to FIG. 4, when a bias voltage is applied to the gate 22, the NP junction formed from the N type junctions 62 and P type implant regions 64 are shorted with the metallizations 56a of the source 24 causing the channel 60 to invert from a P type channel to an N type channel. As a result of the inversion from P type to N type, current flowing into the sources 24 flows horizontally toward the gate 22 as shown by the arrows in FIG. 4. The electrical current then flows vertically downward from the gate 22 as shown by the arrows (as is typical in a vertical transistor structure) until reaching the substrate 52. The electrical current flow is then blocked and electrically isolated by the isolation region 50 causing the current to flow horizontally within the substrate 52, which acts as a drain region for the power MOSFET 20. The current is then conducted vertically upward to the drain 26 as illustrated by the arrows. Thus, when the gate 22 is biased with a voltage, electrical current flows from the one or more sources 24 to the one or more drains 26 through a vertical structure as shown by the arrows in FIG. 4. Electrical current flow out of the bottom side of the power MOSFET 20 is blocked by the isolation region 50, which is formed as part of the multilayer vertical structure as described in more detail above.

As can be seen in FIG. 4, the power MOSFET 20 is mounted directly to a package 80 (e.g., a semiconductor chip package). For example, the bottom 81 of the isolation region 50 (which is the bottom of the power MOSFET 20) can be mounted directly to a base 82 of the package 80. It should be noted that the package 80 is a non-insulating package that does not include, for example, a BeO insulation layer on the base 82 or mounting portion of the package 80. The power MOSFET 80 optionally may be mounted to a mounting region (not shown), for example, a copper pad of the package 80 or directly to the package 80 (or a flange thereof).

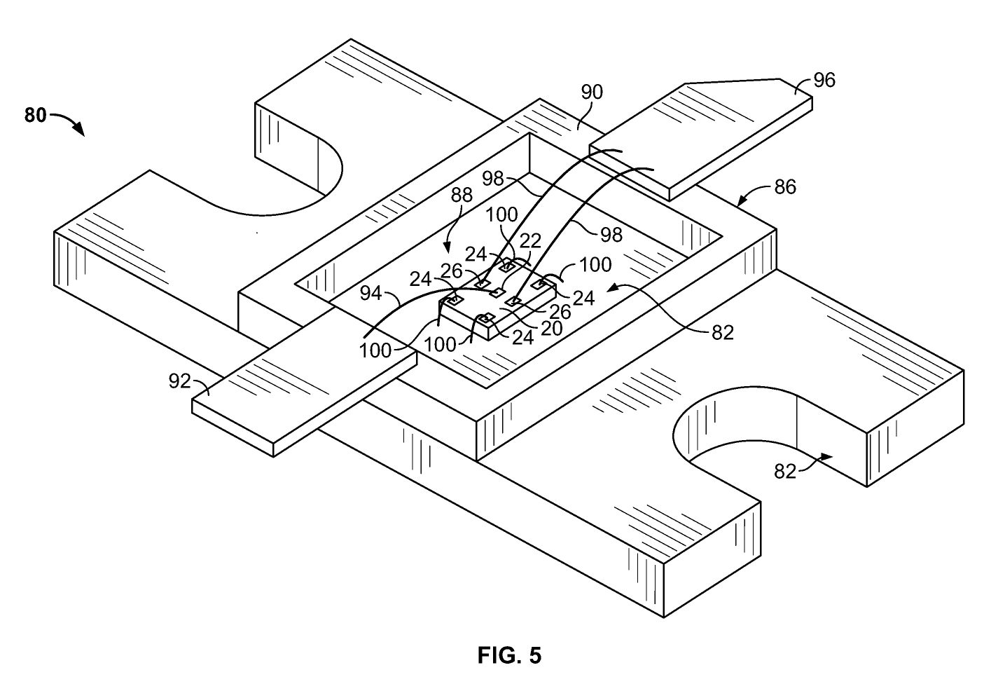

More particularly, as shown in FIGS. 5 and 6, the package 80 for the power MOSFET 20 includes the base 82, which in this embodiment is the metal source flange. The package 80 also includes a frame 86 in which the power MOSFET 20 is mounted. It should be noted that a mounting region 88 within the frame 86 and on which the power MOSFET 20 is mounted does not include any insulating layer, for example, a BeO layer. In the embodiment shown, this mounting region is part of the base 82 defining the metal source flange. Thus, the power MOSFET 20 can be bonded directly to the base 82 (e.g., metal base) without the use of any insulating layer.

The frame 86 also includes along a top edge 90 thereof a gate lead 92 defining a gate bonding pad to which the gate 22 of the power MOSFET 20 is connected. For example, the gate 22 of the power MOSFET 20 may be connected to the gate lead 92 using a wire bond 94. The frame 86 also includes along the top edge 90, for example, on an opposite side, a drain lead 96 defining a drain bonding pad to which one or more drains 26 of the power MOSFET 20 are connected. For example, the one or more drains 26 may be connected to the drain lead 96 using wire bonds 98. One or more sources 24 of the power MOSFET 20 are connected directly to the base 82, defining the metal source flange, using wire bond 100. The wire bonding may be provided as is known in the art.

It should be noted that the gate lead 92 and drain lead 96 may be positioned along any portion of the top edge 90 of the frame 86. The gate lead 92 and drain lead 96 also may be positioned on the same side of the frame 86.

When the power MOSFET 20 is mounted directly to the package 80, the isolation region 50 blocks electrical current from flowing through the bottom of the power MOSFET 20 to the metal surface of the base 82. Additionally, the isolation region 50 thermally conducts heat from the power MOSFET 20 to the metal base 82 such that the heat is dissipated into the surrounding air from the metal base 82. Accordingly, the metal base 82 of the package 80 operates as a heat sink for the power MOSFET 20.

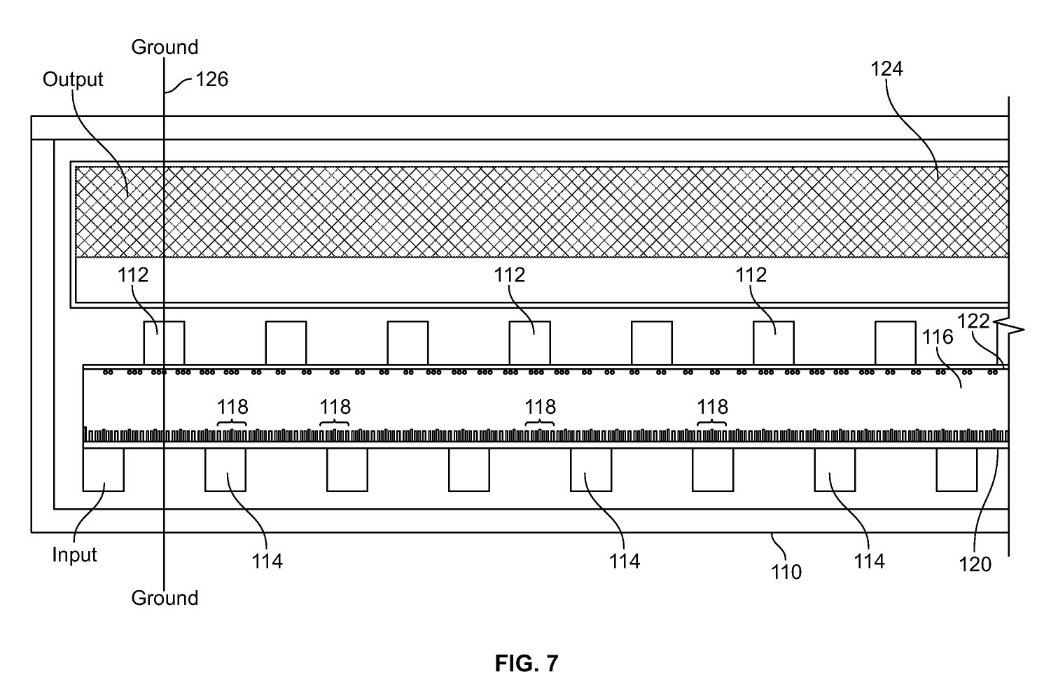

Various embodiments of the invention may provide different configurations for a chip package layout. For example, as shown in FIG. 7, a chip 110 includes a plurality of emitter/source bonding pads 112 and a plurality of base/gate bonding pads 114 on opposite sides of an active transistor area 116 (e.g., metallization), for example, in a MOSFET or BJT. The plurality of emitter/source bonding pads 112 and plurality of base/gate bonding pads 114 are spaced apart and may be staggered on opposite sides of the active transistor area 116 that extends longitudinally along the chip 110. Emitter and base fingers 118 are aligned in parallel in the active transistor area 116. A contact line 120 is provided for connection of all the base/gate bonding pads 114 and a contact line 122 is provided for connection of all the emitter/source bonding pads 112. A top collector/drain contact 124 is also extends longitudinally along the chip 110 parallel to the active transistor area 116.

In one embodiment, one of the emitter/source bonding pads 112 is connected to ground, for example, via one or more wire bonds 126 (two wire bonds 126 on opposite sides of the chip 110 are shown) to a package ground, for example a ground of the chip 110. One of the base/gate bonding pads 114 is connected (e.g., wire bonded) to an input of the chip 110, for example, to operate as a package input terminal for the chip 110. The top collector/drain contact 124 is connected (e.g., wire bonded) to an output of the chip 110, for example, to operate as a package output terminal for the chip 110.

In this embodiment, the positioning of the collector/drain contact 124 along the edge of the chip 110 allows collector/drain wires (not shown) to be positioned adjacent the chip 110 for connection thereto. Accordingly, the signal path is shorter, which minimizes signal loss. Also, the shorter wires can act as a heat sink for the chip 110. Additionally, the horizontal or longitudinal layout of the contacts and pads on the top of the chip 110 can provide improved thermal performance.

Thus, the various embodiments provide a transistor having a vertical structure and that can be mounted to a chip package having no insulation layer. The transistor includes a die-to-ground isolation on a bottom surface with all of the transistor terminals located on a top of the device. Thus, a vertical transistor structure formed in accordance with various embodiments of the invention provides electrical isolation such that the transistor can be mounted directly to a metal package with the terminals wire bonded to the package. Accordingly, instead of having a package that includes, for example, a 40 mil layer of BeO, a 4 mil (or 100 micron) layer of SiO₂ is provided on a bottom surface of the silicon chip forming the transistor. The isolation layer is formed during the semiconductor chip fabrication process as described herein. However, the isolation region 50 and the one or more layers defining the isolation region 50 optionally may be formed during a separate process or mounted to the bottom of the completely fabricated semiconductor chip. It should be noted that unless a hermetically sealed device is needed, no special chip package has to be used, and instead any metal package is suitable.

It also should be noted that although the various embodiments have been described in connection with a MOSFET device having a vertical structure, the isolation layer of the various embodiments and described herein may be implemented in connection with any transistor device. For example, the isolation layer may be formed as part of a vertical BJT device.

Modifications and variations to the various embodiments are contemplated. For example, the positioning and size of the components, terminals and layers may be modified based on the particular application, use, etc. The modification may be based on, for example, different desired or required operating characteristics.

Accordingly, it is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description.

The scope of the various embodiments of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

What is claimed is:

1. A vertical transistor structure comprising:
a vertical semiconductor structure;
an isolation layer on a bottom surface of the vertical semiconductor structure; and
a plurality of terminals on a top surface of the vertical semiconductor structure.

2. A vertical transistor structure in accordance with claim 1 wherein the isolation layer comprises an electrically isolating material.

3. A vertical transistor structure in accordance with claim 1 wherein the isolation layer comprises a thermally conducting material.

4. A vertical transistor structure in accordance with claim 1 wherein the isolation layer comprises silicon dioxide.

5. A vertical transistor structure in accordance with claim 1 wherein the isolation layer is formed as part of the vertical semiconductor structure.

6. A vertical transistor structure in accordance with claim 1 wherein the vertical semiconductor structure defines a Metal Oxide Semiconductor Field-Effect Transistor (MOSFET).

7. A vertical transistor structure in accordance with claim 1 wherein the vertical semiconductor structure defines a Bipolar Junction Transistor (BJT).

8. A vertical transistor structure in accordance with claim 1 wherein the isolation layer comprises a silicon material.

9. A vertical transistor structure in accordance with claim 1 wherein the plurality of terminals are configured to be wire bonded to leads of a package.

10. A power transistor comprising:
a semiconductor chip having a top surface and a bottom surface;
a plurality of terminals on the top surface; and
an integrated isolation region on the bottom surface.

11. A power transistor in accordance with claim 10 wherein the plurality of terminals are configured to connect to leads of a transistor package.

12. A power transistor in accordance with claim 10 wherein the integrated isolation region is configured to be mounted directly to a metal flange of a transistor package.

13. A power transistor in accordance with claim 10 wherein the integrated isolation region comprises silicon dioxide.

14. A power transistor in accordance with claim 10 wherein the semiconductor chip is configured to be mounted to a non-insulating transistor package.

15. A power transistor in accordance with claim 10 wherein the semiconductor chip comprises one of a Metal Oxide Semiconductor Field-Effect Transistor (MOSFET) and a Bipolar Junction Transistor (BJT).

16. A power transistor in accordance with claim 10 wherein the semiconductor chip comprise a vertical structure.

17. A power transistor in accordance with claim 10 wherein the semiconductor chip comprises a radio frequency (RF) device.

18. A method of fabricating a vertical transistor structure, the method comprising:
forming a plurality of terminals on a top surface of a semiconductor chip; and
forming an integrated isolation layer on a bottom surface of the semiconductor chip such that electrical current flowing vertically downward from at least one of the plurality of terminals is blocked and directed vertically upward to another one of the plurality of terminals.

19. A method in accordance with claim 18 further comprising forming the integrated isolation layer from silicon dioxide.

20. A method in accordance with claim 18 further comprising forming the integrated isolation later from a thermally conducting material.
